(19) United States
(12) Patent Application Publication
(10) Pub. No.: US 2026/0059841 A1
(43) Pub. Date: Feb. 26, 2026

(54) SEMICONDUCTOR DEVICE HAVING A TRANSISTOR STRUCTURE AND A METHOD OF MANUFACTURING THE SEMICONDUCTOR DEVICE

(71) Applicant: SK hynix Inc., Gyeonggi-do (KR)

(72) Inventor: Min Soo YOO, Gyeonggi-do (KR)

(21) Appl. No.: 19/082,180

(22) Filed: Mar. 18, 2025

(30) Foreign Application Priority Data
Aug. 22, 2024 (KR) 10-2024-0112638

(51) Int. Cl. H10D 64/68; H01L 21/28; H10D 30/62; H10D 64/01; H10D 64/66; H10D 84/83

(52) U.S. Cl. CPC H10D 64/685; H01L 21/2822; H10D 30/6217; H10D 64/01; H10D 64/669; H10D 84/834

(57) ABSTRACT

A semiconductor device having a transistor structure is described. The transistor structure comprises a fin active region vertically protruding from a substrate and extending in a first horizontal direction; and a gate structure crossing the fin active region and extending in a second horizontal direction. The gate structure includes an upper gate structure disposed over the fin active region, the upper gate structure having a line shape extending in the second horizontal direction; and a lower gate structure disposed on both sides of the fin active region. The lower gate structure has a first horizontal width in the first horizontal direction. The upper gate structure has a second horizontal width in the first horizontal direction. The first horizontal width is less than the second horizontal width.

### CROSS-REFERENCE TO RELATED APPLICATIONS

The present application claims priority under 35 U.S. C. 119(a) to Korean Patent Application No. 10-2024-0112638, filed on Aug. 22, 2024, which is incorporated herein by reference in its entirety.

### BACKGROUND

### 1. Field

Various embodiments of the present disclosure relate generally to semiconductor technology and, in particular, to a semiconductor device having a transistor structure and a method of manufacturing the semiconductor device having the transistor structure.

### 2. Description of the Related Art

As patterns of semiconductor devices became more refined, damage due to interference and processes emerged as factors that could not be ignored. Improved structures are needed that mitigate interference.

### SUMMARY

An embodiment of the present disclosure provides a new transistor structure for a semiconductor device having the transistor structure that significantly reduces electrical interference between various parts of the transistor structure.

Another embodiment of the present disclosure provides a semiconductor device having the transistor structure.

Another embodiment of the present disclosure provides a method of forming the transistor structure.

Yet another embodiment of the present disclosure provides a method of manufacturing a semiconductor device having the transistor structure.

In accordance with an embodiment of the present disclosure, a semiconductor device having a transistor structure is described. The transistor structure comprises a fin active region vertically protruding from a substrate and extending in a first horizontal direction; and a gate structure crossing the fin active region and extending in a second horizontal direction. The gate structure includes an upper gate structure disposed over the fin active region, the upper gate structure having a line shape extending in the second horizontal direction; and a lower gate structure disposed on both sides of the fin active region. The lower gate structure has a first horizontal width in the first horizontal direction. The upper gate structure has a second horizontal width in the first horizontal direction. The first horizontal width is less than the second horizontal width.

In accordance with another embodiment of the present disclosure, semiconductor device having a transistor structure is described. The transistor structure comprises fin active regions vertically protruding from a substrate and extending parallel with each other in a first horizontal direction; isolation regions between the fin active regions to define the fin active regions; and gate structures extending in parallel with each other to cross the fin active regions and the isolation regions in a second horizontal direction. Each of the gate structures includes an upper gate structure having a line shape disposed over the fin active regions and extending in the second horizontal direction; and lower gate structures disposed between the fin active regions. Each of the lower gate structures has a first horizontal width in the first horizontal direction. Each of the upper gate structures has a second horizontal width in the first horizontal direction. The first horizontal width is less than the second horizontal width.

In accordance with another embodiment of the present disclosure, a method of manufacturing a semiconductor device having a transistor structure is described. The method comprises recessing some portions of a substrate to form trenches; forming isolation regions by filling the trenches with insulating materials, the isolation regions defining fin active regions extending in parallel with each other in the first horizontal direction; recessing the isolation regions between the fin active regions to form grooves exposing some portions of side surfaces of the fin active regions; and forming gate structures extending in parallel with each other to cross the fin active regions and the isolation regions in the second horizontal direction. Each of the gate structures comprises an upper gate structure disposed over surfaces of the fin active regions and extending in the second horizontal direction; and lower gate structures formed in the grooves. A horizontal width of each of the lower gate structures is less than a horizontal width of the upper gate structure in the first horizontal direction.

In accordance with another embodiment of the present disclosure, a transistor structure for a semiconductor device, the transistor structure comprises a plurality of spaced apart fin active regions vertically protruding above a top surface of a substrate, arranged parallel to each other at regular intervals, wherein each fin active region has a dam shape with a wider base and narrower top, a plurality of gate structures crossing over the fin active regions, wherein each of the gate structures includes an upper gate structure disposed over the fin active region and a lower gate structure disposed on both sides of a corresponding fin active region. A width of the lower gate structure in the first horizontal direction is less than a width of the upper gate structure.

These and other features and advantages of the embodiments of the present disclosure will become better understood by those with ordinary skill in the art from the following detailed description in conjunction with the following figures.

### BRIEF DESCRIPTION OF THE DRAWINGS

FIG. 1 is a perspective view of a transistor structure 100 of a semiconductor device according to an embodiment of the present disclosure.

FIG. 2 is a top view of the transistor structure 100.

FIGS. 3A to 3C are longitudinal cross-sectional views taken along lines I-I′, II-II′, and III-III′ of FIG. 2.

FIGS. 4A, 4B, and 4C to 9A, 9B, and 9C are views illustrating a method of manufacturing a semiconductor device according to an embodiment of the present disclosure.

### DETAILED DESCRIPTION

Various embodiments of the present disclosure are described in detail with reference to the accompanying drawings. Specific structural or functional descriptions of the embodiments are provided as examples to describe specific example implementations of the technical concepts of the present disclosure. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with these areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

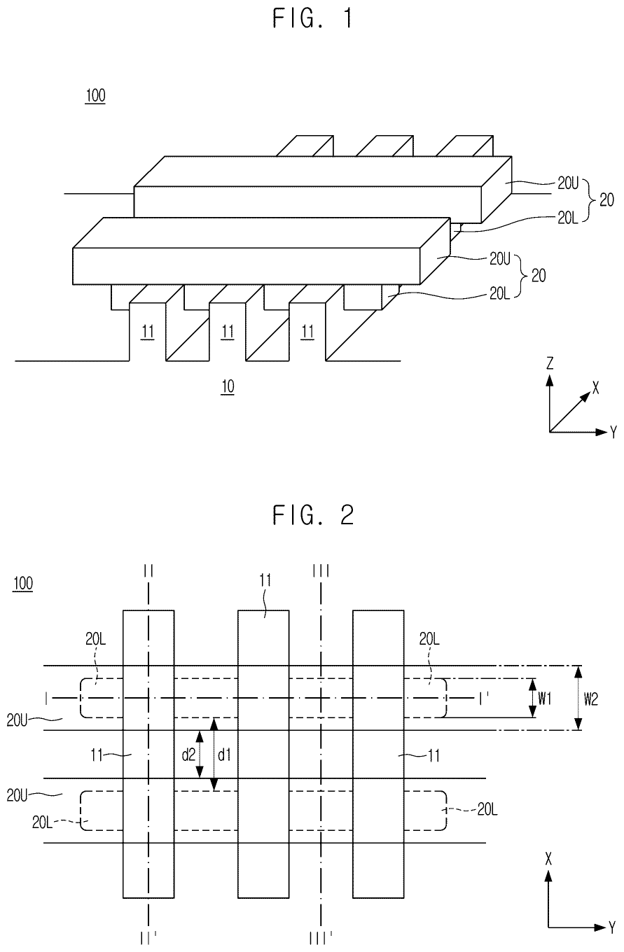

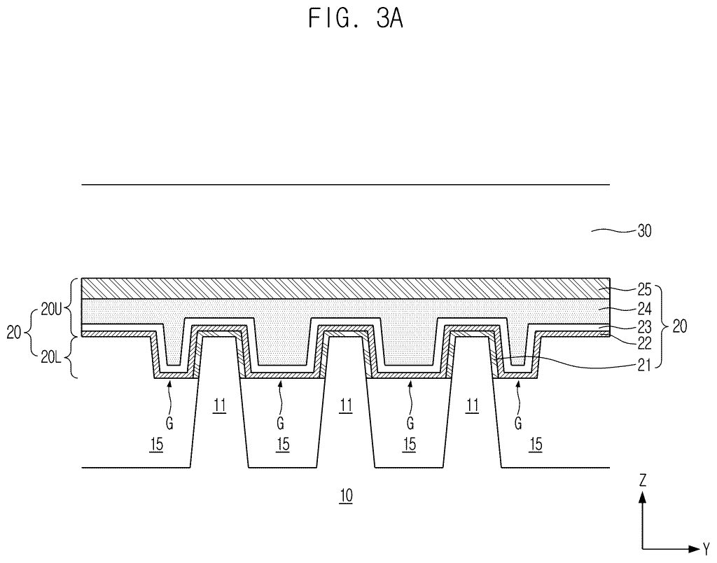

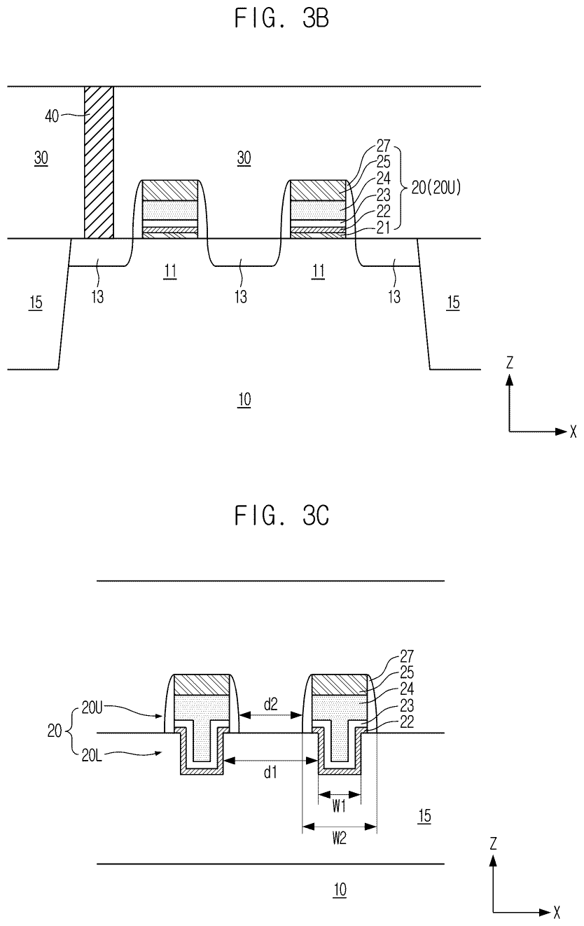

FIG. 1 is a perspective view of a transistor structure 100 of a semiconductor device according to an embodiment of the present disclosure, FIG. 2 is a top view of the transistor structure 100, and FIGS. 3A to 3C are longitudinal cross-sectional views taken along lines I-I′, II-II′, and III-III′ of FIG. 2.

Referring to FIGS. 1 and 2, the transistor structure 100 may include fin active regions 11 and gate structures 20. The fin active regions 11 may protrude upward from the substrate 10 in a vertical direction Z. The fin active regions 11 may have a shape of dams extending parallel with each other in a first horizontal direction X. The gate structures 20 may include upper gate structures 20U and lower gate structures 20L. The upper gate structures 20U may each have a line shape extending in a second horizontal direction Y. The upper gate structures 20U may be arranged parallel to each other. The upper gate structure 20U may extend in the second horizontal direction Y to cross the fin active regions 11. The lower gate structures 20L may protrude downward from the upper gate structure 20U into spaces created between the fin active regions 11. The lower gate structures 20L may partially surround the side surfaces of the fin active regions 11. That is, each of the lower gate structures 20L may have a fin gate structure. In FIG. 2, because the lower gate structures 20L are not visible from a top view, the lower gate structures 20L are indicated by dotted lines. Each of the lower gate structures 20L may have a first horizontal width W1 in the first horizontal direction X. The upper gate structure 20U may have a second horizontal width W2 in the first horizontal direction X. The first horizontal width W1 may be less than the second horizontal width W2. The lower gate structures 20L may be spaced apart from each other by a first horizontal distance d1 in the first horizontal direction X, and the upper gate structures 20U may be spaced apart from each other by a second horizontal distance d2 in the first horizontal direction X. The first horizontal distance d1 may be greater than the second horizontal distance d2.

Referring to FIGS. 3A to 3C, the transistor structure 100 may include a plurality of fin active regions 11 protruding upward from the substrate 10 in the vertical direction Z and the gate structures 20 which are positioned over the fin active regions 11. The fin active regions 11 may have a dam shape with a wider base than a top surface. The fin active regions 11 may include source/drain regions 13, respectively. The fin active regions 11 may be portions of the substrate 10. The fin active regions 11 may be defined by isolation regions 15. For example, the fin active regions 11 may be disposed between the isolation regions 15. In an embodiment, the isolation regions 15 may be disposed between the fin active regions 11. The source/drain regions 13 may be portions of the fin active regions 11. The source/drain regions 13 may be formed by implanting impurity ions into the fin active regions 11. The impurity ions may include at least one of phosphorus (P) ions, arsenic (As) ions, boron (B) ions, boron fluoride (BF₂) ions, or carbon (C) ions. The semiconductor device may further include an interlayer insulating layer 30 covering the transistor structure 100. The interlayer insulating layer 30 may include an insulating material such as silicon oxide. The semiconductor device may further include a via plug 40 vertically passing through the interlayer insulating layer 30 to be in direct contact with one of the source/drain regions 13 of the fin active regions 11. The via plug 40 may include a conductive material such as a metal. In an embodiment, the semiconductor device may include a plurality of via plugs 40 respectively connected to the source/drain regions 13.

Each of the gate structures 20 may include interfacial insulating layers 21, a high-k dielectric layer 22, a barrier layer 23, a gate electrode 24, a gate capping layer 25, and a gate spacer 27. The interfacial insulating layers 21 may be disposed on the surfaces of the fin active regions 11. In an embodiment, the interfacial insulating layers 21 may be formed by oxidizing the surfaces of the fin active regions 11. Thus, each of the interfacial insulating layers 21 may include an insulating material layer based on a silicon oxide. The interfacial insulating layers 21 may be discretely and discontinuously disposed in the second horizontal direction Y so that they do not cover the isolation regions 15 as illustrated in FIG. 3A. In an embodiment, the interfacial insulating layers 21 may only be disposed above the top surface and the upper portions of the side surfaces of the active fin regions 11. The high-k dielectric layer 22 may be disposed on the interfacial insulating layers 21 and the isolation regions 15. The high-k dielectric layer 22 may include an insulating layer having a dielectric constant higher than that of the silicon oxide layer, such as, f or example, a hafnium oxide layer, a zirconium oxide layer, or a hafnium zirconium oxide layer. In an embodiment, the gate structure 20 may further include a dipole material layer disposed on the high-k dielectric layer 22. The dipole material layer may include at least one of a lanthanum oxide layer, an aluminum oxide layer, or a lanthanum aluminum oxide layer. The dipole material, including lanthanum oxide (La₂O₃), aluminum oxide (Al₂O₃), or lanthanum aluminum oxide (LaAlO₃) may be formed through several deposition or fabrication methods. Referring now back to the illustrated embodiment of FIG. 3A, the barrier layer 23 may be disposed on the high-k dielectric layer 22. The barrier layer 23 may be disposed to be in direct contact with the high-k dielectric layer 22. The barrier layer 23 may include a metal nitride layer. For example, the barrier layer 23 may include a titanium nitride layer. In an embodiment, the barrier layer 23 may include a dipole material. For example, the barrier layer 23 may include at least one of a lanthanum titanium nitride layer, an aluminum titanium nitride layer, or a lanthanum aluminum nitride layer. The gate electrode 24 may be disposed on the barrier layer 23. The gate electrode 24 may be disposed to be in direct contact with the barrier layer 23. The gate electrode 24 may include a conductive material such as a metal. For example, the gate electrode 24 may include tungsten. The gate capping layer 25 may be disposed on the gate electrode 24. The gate capping layer 25 may be disposed to be in direct contact with the gate electrode 24. The gate capping layer 25 may include an insulating material having an etching selectivity with respect to silicon oxide. For example, the gate capping layer 25 may include a silicon nitride layer. As illustrated in FIG. 3B, the gate spacer 27 may be disposed to be in direct contact with side surfaces of the interfacial insulating layer 21, the high-k dielectric layer 22, the barrier layer 23, the gate electrode 24, and the gate capping layer 25. The gate spacer 27 may include an insulating material having an etching selectivity with respect to silicon oxide. For example, the gate spacer 27 may include silicon nitride. The high-k dielectric layer 22, the barrier layer 23, the gate electrode 24, the gate capping layer 25, and the gate spacer 27 may be continuous and extend in the second horizontal direction Y. In the embodiment, the high-k dielectric layer 22 and the barrier layer 23 may be horizontally formed only under a bottom portion of the gate structure 20. That is, the high-k dielectric layer 22 and the barrier layer 23 may not be disposed on the sidewalls of the gate structure 20.

The gate structure 20 may include an upper gate structure 20U and lower gate structures 20L. The upper gate structure 20U may be disposed on the fin active regions 11 and the isolation regions 15. The upper gate structure 20U may cross the fin active regions 11 and the isolation regions 15. The upper gate structure 20U may extend in the second horizontal direction Y. The lower gate structures 20L may be disposed within the isolation regions 15 between the fin active regions 11. The lower gate structures 20L may protrude downward from the upper gate structure 20U into the isolation regions 15 between the fin active regions 11. For example, as illustrated in FIG. 3A the lower gate structures 20L may fill grooves G formed in the isolation regions 15 between fin active regions 11. The lower gate structures 20L may partially surround the side surfaces of the fin active regions 11. The high-k dielectric layer 22 and the barrier layer 23 may be conformally formed on the side surfaces and bottom surfaces of the lower gate structures 20L. That is, the high-k dielectric layer 22 and the barrier layer 23 may be conformally formed on the side surfaces and bottom surfaces of the grooves G. In the grooves G, i.e., in the lower gate structure 20L, the high-k dielectric layer 22 and the barrier layer 23 may form a U-shaped cross-sectional structure. The gate electrode 24 may include lower portions protruding downward from the upper gate structure 20U to the lower gate structure 20L. Lower portions of the gate electrode 24 may be disposed on the high-k dielectric layer 22 to fill the grooves G. The lower portions of the gate electrode 24 may have a T-shaped cross-sectional structure. The isolation regions 15 may surround and support the bottom surfaces of the corresponding lower gate structures 20L between the fin active regions 11.

The lower gate structure 20L may have a first horizontal width W1 in the first horizontal direction X. The upper gate structure 20U may have a second horizontal width W2 in the first horizontal direction X. The first horizontal width W1 may be less than the second horizontal width W2. That is, the horizontal width W1 of the lower gate structure 20L may be less than the horizontal width W2 of the upper gate structure 20U. A distance between the lower gate structures 20L in the first horizontal direction X may be a first horizontal distance d1, and a distance between the upper gate structures 20U in the first horizontal direction X may be a second horizontal distance d2. The first horizontal distance d1 may be greater than the second horizontal distance d2. The lower gate structures 20L may provide a fin gate structure. Since the first horizontal width W1 of the lower gate structures 20L is less than the second horizontal width W2 of the upper gate structures 20U, the first horizontal distance d1 between the adjacent lower gate electrodes 20L may be greater than the second horizontal distance d2 between the adjacent upper gate electrodes 20U. In this manner, a distance between the source/drain regions 13 and the lower gate structure 20L may increase (move away with each other). Accordingly, electrical interference between the lower gate structures 20L, and between the source/drain electrodes 13 and the gate electrode 24 may be reduced. For example, the electrical bridge, electrical coupling, and parasitic capacitance between the lower gate structures 20L and/or between the source/drain regions 13 and the gate electrode 24 may be reduced. Accordingly, the performance of the gate structure 20, the transistor structure 100, and the semiconductor device may be improved.

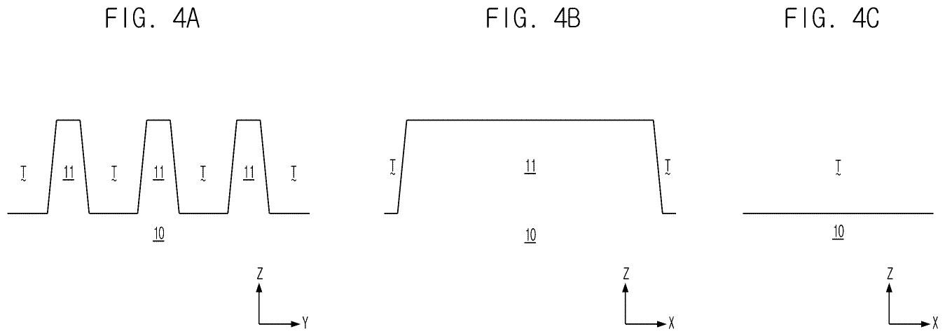

FIGS. 4A, 4B, and 4C to 9A, 9B, and 9C are views illustrating a method of manufacturing a semiconductor device according to an embodiment of the present disclosure. FIGS. 4A, 5A, 6A, 7A, 8A, and 9A are longitudinal cross-sectional views taken along the line I-I′ of FIG. 2, FIGS. 4B, 5B, 6B, 7B, 8B, and 9B are longitudinal cross-sectional views taken along the line II-II′ of FIG. 2, and FIGS. 4C, 5C, 6C, 7C, 8C, and 9C are longitudinal cross-sectional views taken along the line III-III′ of FIG. 2.

Referring to FIGS. 4A to 4C, the method may include forming trenches T by recessing some regions of a substrate 10. The method may include performing a recess process, e.g., an etching process. For example, the method may include forming an etch mask pattern (not shown) on the substrate 10 and performing a selective etching process using the mask pattern as an etch mask. The trenches T may define fin active regions 11 having a protruding shape. Each of the fin active regions 11 may have a dam shape or a bar shape extending in a first horizontal direction X.

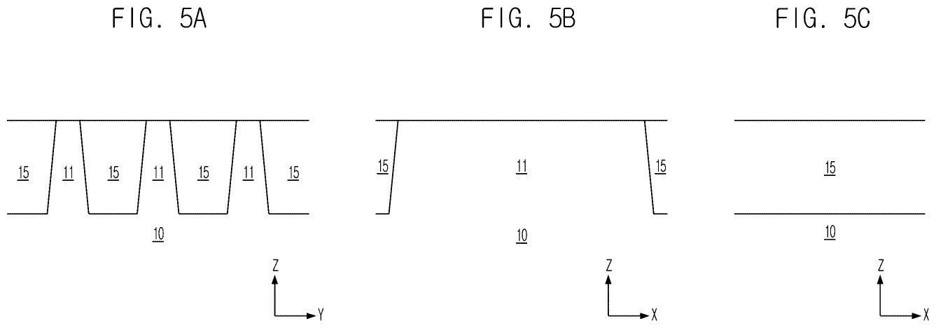

Referring to FIGS. 5A to 5C, the method may further include forming isolation regions 15 by filling an inside of the trenches T with an insulating material. The isolation regions 15 may include at least one of silicon oxide, silicon nitride, or other insulating materials. In an embodiment, the isolation regions 15 may include silicon oxide. The method may further include co-planarizing surfaces of the fin active regions 11 and surfaces of the isolation regions 15. For example, the method may include performing a planarization process such as a chemical mechanical polishing (CMP) process.

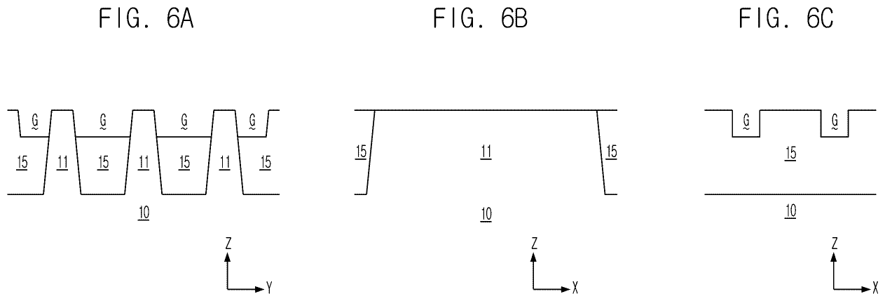

Referring to FIGS. 6A to 6C, the method may further include forming grooves G in the isolation regions 15 by performing a groove forming process. Each groove 15 may be formed by recessing a portion of each isolation region 15 that is adjacent to the protruding fin active region 11. The grooves G may expose upper portions of side surfaces of the fin active regions 11. The surfaces of the isolation regions 15 may be exposed on a bottom and sidewalls of the grooves G.

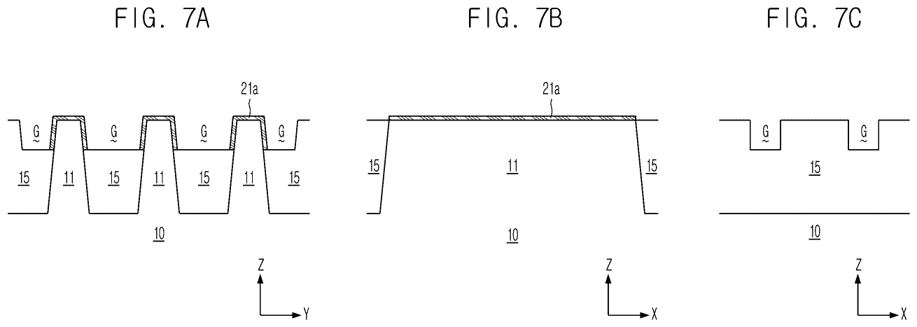

Referring to FIGS. 7A to 7C, the method may further include forming an interfacial insulating material layer 21a on the exposed surfaces of the fin active regions 11 by performing an oxidation process. The interfacial insulating material layer 21a may include silicon oxide or silicon oxynitride. For example, the interfacial insulating material layer 21a may be formed only on the fin active regions 11 and may not be formed on the surface of the isolation regions 15.

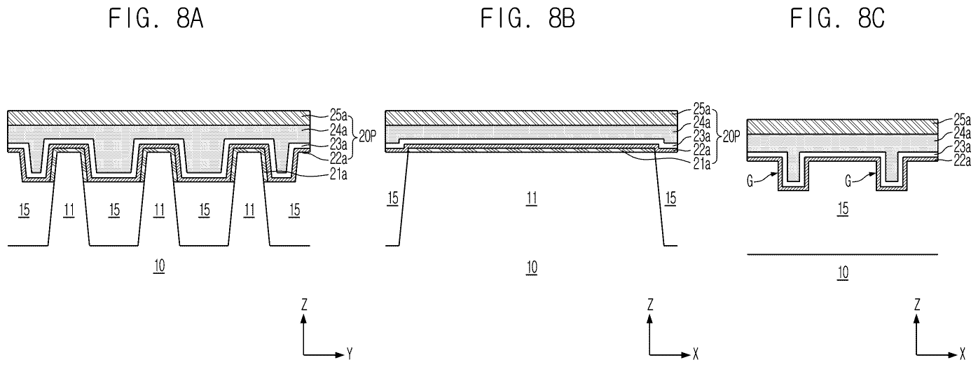

Referring to FIGS. 8A to 8C, the method may further include forming a high-k dielectric material layer 22a, a barrier material layer 23a, a gate electrode material layer 24a, and a gate capping material layer 25a by performing deposition processes to form preliminary gate structures 20P. The high-k dielectric material layer 22a may include at least one of a hafnium oxide (HfO) layer, a hafnium oxide (HfON) layer, a zirconium oxide (ZrON) layer, a zirconium hafnium oxide (ZrHfO) layer, a zirconium hafnium oxide (ZrHfON) layer, or other metal oxide layers. The barrier material layer 23a may include a titanium nitride layer. In an embodiment, the barrier material layer 23a may further include a dipole material. For example, the barrier material layer 23a may include a titanium nitride layer containing at least one of lanthanum (La) or aluminum (Al). The gate electrode material layer 24a may include at least one of an N-doped polycrystalline silicon layer, a metal nitride layer, and a metal layer. The N-doped polycrystalline silicon layer may include phosphorus (P) and/or arsenic (As). For example, the metal nitride layer may include a titanium nitride layer. For example, the metal layer may include a tungsten (W) layer. The gate capping material layer 25a may include an insulating material layer having etch selectivity with respect to silicon oxide. For example, the gate capping material layer 25a may include at least one of a silicon nitride (SiN) layer, a silicon oxide nitride (SiON), silicon boron nitride (SiBN), silicon carbide (SiCN), or a combination thereof. The high-k dielectric material layer 22a and the barrier material layer 23a may be conformally formed on a surface of the interfacial insulating material layer 21a and the surface of the isolation region 15. The high-k dielectric material layer 22a and the barrier material layer 23a may be conformally formed on the surfaces of the isolation regions 15 exposed in the grooves G. The gate electrode material layer 24a may completely fill the grooves G.

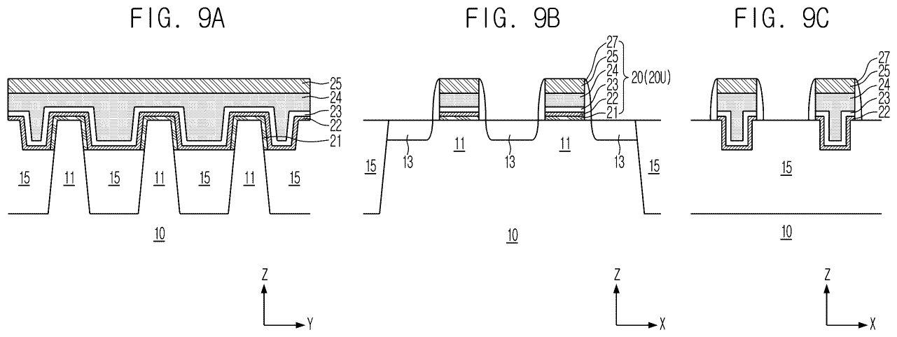

Referring to FIGS. 9A to 9C, the method may further include patterning the preliminary gate structures 20P, to form gate spacers 27 and source/drain regions 13. For example, the method may include forming a gate mask pattern (not shown) on the preliminary gate structures 20P, forming an interfacial insulating layer 21, a high-k dielectric layer 22, a barrier layer 23, a gate electrode 24, and a gate capping layer 25 by performing a selective etching process using the gate mask pattern as an etching mask, removing the gate mask pattern, forming gate spacers 27 on sidewalls of the interfacial insulating layer 21, the high-k dielectric layer 22, the barrier layer 23, the gate electrode 24, and the gate capping layer 25, and forming source/drain regions 13 in the fin active region 11 by performing an ion implantation process using the gate spacers 27 as an ion implantation mask. The gate spacers 27 may include at least one of silicon nitride, silicon oxide, silicon oxide nitride, silicon boron nitride, or silicon carbide nitride. In an embodiment, the gate spacers 27 may include a multilayer structure. The ion implantation process may include implanting at least one of phosphorus (P) ions, arsenic (As) ions, boron (B) ions, and boron fluoride (BF₂) ions into the exposed regions of the fin active regions 11.

Thereafter, referring to FIGS. 3A to 3C, the method may further include forming an interlayer insulating layer 30 and forming a via plug 40 passing through the interlayer insulating layer 30 to contact the source/drain region 13. Forming the interlayer insulating layer 30 may include forming an insulating material such as silicon oxide to be thick enough to cover the gate structures 20 by performing a deposition process such as chemical vapor deposition (CVD) or plasma-enhanced chemical vapor deposition (PECVD). In CVD, a gaseous mixture of silicon precursors (such as silane (SiH₄) or tetraethyl orthosilicate (TEOS)) and oxygen may be introduced into the deposition chamber. The precursors react at elevated temperatures to form a silicon oxide layer on the surface of the gate structures and the surrounding substrate. The PECVD may be used to deposit silicon oxide at lower temperatures compared to the CVD. The insulating layer is made thick enough to provide sufficient coverage and insulation, and it may undergo planarization and optional post-deposition treatments to ensure quality and proper performance. Forming the via plug 40 may include forming a via hole vertically penetrating the interlayer insulating layer 30 to expose a portion of the source/drain regions 13 of the fin active region 11, and filling inside of the via hole with a conductive material.

According to the embodiments of the present disclosure, the distance between the fin gate electrodes of the transistor structure and the distance between the source/drain region and the fin gate electrode can be sufficiently secured. Accordingly, electrical interference between the fin gate electrodes, and electrical interference between the source/drain region and the fin gate electrode can be reduced. Damage to the fin active region due to an etching process for forming the fin transistor structure can be reduced. Electrical performance of the gate structure, the transistor structure, and the semiconductor device can be improved.

While the embodiments of the present disclosure have been described with respect to specific embodiments, it will be apparent to those skilled in the art that various changes and modifications may be made without departing from the technical concepts and scope of the present disclosure as defined in the following claims. Furthermore, the embodiments may be combined to form additional embodiments.

1. A semiconductor device having a transistor structure, wherein the transistor structure comprises:
a fin active region vertically protruding from a substrate and extending in a first horizontal direction; and
a gate structure crossing the fin active region and extending in a second horizontal direction,
wherein the gate structure includes:
an upper gate structure disposed over the fin active region, wherein the upper gate structure has a line shape extending in the second horizontal direction; and
a lower gate structure disposed on both sides of the fin active region,
wherein:
the lower gate structure has a first horizontal width in the first horizontal direction,
the upper gate structure has a second horizontal width in the first horizontal direction, and
the first horizontal width is less than the second horizontal width.

2. The semiconductor device of claim 1,
wherein the fin active region has a dam shape or a bar shape extending in the first horizontal direction.

3. The semiconductor device of claim 1,
wherein the gate structure further includes:
an interfacial insulating layer disposed over a surface of the fin active region;
a high-k dielectric layer disposed over the interfacial insulating layer;
a barrier layer disposed over the high-k dielectric layer; and
a gate electrode disposed over the barrier layer.

4. The semiconductor device of claim 3,
wherein the high-k dielectric layer and the barrier layer are conformally disposed under portions of a bottom surface of the upper gate structure and over sidewalls and a bottom surface of the lower gate structure.

5. The semiconductor device of claim 3,
wherein the interfacial insulating layer includes an insulating layer based on silicon oxide formed by oxidizing the surface of the fin active region.

6. The semiconductor device of claim 2,
wherein the gate structure further includes a dipole material layer between the high-k dielectric layer and the barrier layer, and
wherein the dipole material layer contains an oxide layer including at least one of lanthanum or aluminum.

7. The semiconductor device of claim 1,
wherein the interfacial insulating layers are discontinuously disposed over the fin active regions in the second horizontal direction.

8. The semiconductor device of claim 3,
wherein the high-k dielectric layer, the barrier layer, the gate electrode, and the gate capping layer are continuously formed to extend in the second horizontal direction.

9. The semiconductor device of claim 1, further comprising:
a gate spacer in direct contact with side surfaces of the interfacial insulating layer, the high-k dielectric layer, the barrier layer, the gate electrode, and the gate capping layer.

10. A semiconductor device having a transistor structure, wherein the transistor structure comprises:
fin active regions vertically protruding from a substrate and extending parallel with each other in a first horizontal direction;
isolation regions between the fin active regions to define the fin active regions; and
gate structures extending in parallel with each other to cross the fin active regions and the isolation regions in a second horizontal direction,
wherein each of the gate structures includes:
an upper gate structure having a line shape disposed over the fin active regions and extending in the second horizontal direction; and
lower gate structures disposed between the fin active regions,
wherein each of the lower gate structures has a first horizontal width in the first horizontal direction,
wherein each of the upper gate structures has a second horizontal width in the first horizontal direction, and
wherein the first horizontal width is less than the second horizontal width.

11. The semiconductor device of claim 10,
wherein the lower gate structures are spaced apart from each other with a first horizontal distance in the first direction,
wherein the upper gate structures are spaced apart from each other with a second horizontal distance in the first direction, and
wherein the first horizontal distance is greater than the second horizontal distance.

12. The semiconductor device of claim 10,
wherein the isolation regions surround and support bottom surfaces of the lower gate structures.

13. The semiconductor device of claim 10,
wherein each of the gate structures includes:
interfacial insulating layers over surfaces of the fin active regions;
a high-k dielectric layer disposed over the interfacial insulating layers and extending in the first direction;
a barrier layer over the high-k dielectric layer; and
a gate electrode over the barrier layer.

14. The semiconductor device of claim 13,
wherein the high-k dielectric layer and the barrier insulating layer are disposed over a bottom surface of each of the upper gate structures, and conformally disposed over sidewalls and a bottom surface of each of the lower gate structures.

15. A method of manufacturing a semiconductor device having a transistor structure, the method comprises:
recessing some portions of a substrate to form trenches;
forming isolation regions by filling the trenches with insulating materials, wherein the isolation regions define fin active regions extending in parallel with each other in the first horizontal direction;
recessing the isolation regions between the fin active regions to form grooves exposing some portions of side surfaces of the fin active regions; and
forming gate structures extending in parallel with each other to cross the fin active regions and the isolation regions in the second horizontal direction,
wherein each of the gate structures comprises:
an upper gate structure disposed over surfaces of the fin active regions and extending in the second horizontal direction; and
lower gate structures formed in the grooves,
wherein a horizontal width of each of the lower gate structures is less than a horizontal width of the upper gate structure in the first horizontal direction.

16. The method of claim 15,
wherein forming the gate structure includes:
forming interfacial insulating material layers over the surfaces and the exposed side surfaces of the fin active regions;
forming a high-k dielectric material layer over the interfacial insulating material layers and surfaces of isolation regions exposed in the grooves;
forming a barrier material layer over the high-k dielectric material layer;
forming a gate electrode material layer over the barrier material layer;
forming a gate capping material layer over the gate electrode material layer;
patterning the gate capping material layer, the gate electrode material layer, the barrier material layer, the high-k dielectric material layer, and the interfacial insulating material layer to form a preliminary gate structure; and
forming a gate spacer on a side surface of the preliminary gate structure.

17. The method of claim 16,
wherein forming the interfacial insulating material layer includes oxidizing the surfaces of the exposed fin active regions by performing an oxidation process.

18. The method of claim 16,
wherein forming the high-k dielectric material layer includes forming a metal oxide layer over the surfaces of the interfacial insulating material layer and the isolation regions by performing a deposition process.

19. The method of claim 16, further comprising:
forming a dipole material layer between the high-k dielectric material layer and the barrier material layer,
wherein the dipole material layer includes an oxide layer containing at least one of lanthanum or aluminum.

20. The method of claim 15,
wherein the lower gate structures are spaced apart from each other to have a first horizontal distance in the first direction,
wherein the upper gate structures are spaced apart from each other to have a second horizontal distance in the first direction, and
wherein the first horizontal distance is greater than the second horizontal distance.

21. A transistor structure for a semiconductor device, the transistor structure comprising:
a plurality of spaced apart fin active regions vertically protruding above a top surface of a substrate, arranged parallel to each other at regular intervals, wherein each fin active region has a dam shape with a wider base and narrower top,
a plurality of gate structures crossing over the fin active regions,
wherein each of the gate structures includes an upper gate structure disposed over the fin active region and a lower gate structure disposed on both sides of a corresponding fin active region,
wherein:
a width of the lower gate structure in the first horizontal direction is less than a width of the upper gate structure.
